(19) United States
(12) Patent Application Publication
(10) Pub. No.: US 2011/0126063 A1
(43) Pub. Date: May 26, 2011

(54) METHOD FOR INSERTING TEST POINTS FOR LOGIC CIRCUITS AND LOGIC CIRCUIT TESTING APPARATUS

(75) Inventor: Eiji HARADA, Kanagawa (JP)

(73) Assignee: RENESAS ELECTRONICS CORPORATION, Kanagawa (JP)

(21) Appl. No.: 12/950,743

(22) Filed: Nov. 19, 2010

(30) Foreign Application Priority Data
Nov. 25, 2009 (JP) 2009-267386

(51) Int. Cl. G01R 31/3177; G06F 11/25

(52) U.S. Cl. 714/724; 714/E11.155

(57) ABSTRACT

This invention is intended to insert test points in a logic circuit under test in an effective manner. The logic circuit testing apparatus includes a fault estimation unit that estimates fault likelihoods for each of signal lines in a logic circuit in accordance with wiring conditions obtained from design data for the logic circuit. The logic circuit testing apparatus also includes an insertion unit that inserts test points, based on the fault likelihoods. The logic circuit testing apparatus executes testing the logic circuit in which the test points were inserted by the insertion unit.

### CROSS-REFERENCE TO RELATED APPLICATIONS

The disclosure of Japanese Patent Application No. 2009-267386 filed on Nov. 25, 2009 including the specification, drawings and abstract is incorporated herein by reference in its entirety.

### BACKGROUND OF THE INVENTION

The present invention relates to a method for inserting test points for logic circuits and a logic circuit testing apparatus.

In recent years, logic integrated circuits (logic ICs) such as SOC (system-on-a-chip) have become more complicated and larger. Due to this, how to detect a stuck-at fault which may exist in a logic IC becomes a major challenge. In general, in order to detect a stuck-at fault in a logic IC, an input signal (test pattern) for testing the circuit is input and it is checked whether an intended output pattern is yielded. It is desirable to input test patterns to the logic IC in an efficient manner and quickly detect a stuck-at fault in the logic IC.

Patent document 1 discloses a method for creating test patterns for logic ICs, wherein the method is capable of creating test patterns to efficiently test a logic IC before the completion of the logic IC. The method for creating test patterns for logic ICs described in patent document 1 will be outlined below.

The foregoing method estimates the fault possibilities of signal lines according to wiring conditions, using design data for a logic IC before its completion and creates test patterns which are pairs of an input pattern and its expected value pattern in descending order of the estimated fault possibilities. The estimation of a fault possibility for a signal line may be calculated, based on the number of intersections of the signal line with power supply routing lines and ground lines in different wiring layers, the length of the signal line, the number of alternate routes for the signal line, and wiring density. The following description discusses estimating the fault possibilities of signal lines in terms of the lengths of the signal lines. FIG. 6 is a block diagram illustrating a logic IC under test. FIG. 3 tabulates signal lines and their lengths obtained from design data for the logic IC illustrated in FIG. 6. FIG. 5 is a flowchart illustrating the processing flow of the method for creating test patterns for logic ICs described in patent document 1.

First, a step of estimating the fault possibilities of signal lines is performed (S11). Here, this step refers to the lengths of the signal lines in FIG. 3 calculated from the design data. Then, sorting the signal lines based on the calculated fault possibilities is performed (S12). The sorting step orders the signal lines in descending order of the fault possibilities. In the example of FIG. 3, the signal lines are reordered as: C (10), D (7), A (5), B (4), and E (3). For the signal lines, test patterns are then created (S13) in a manner as below: a fault is assumed to occur more likely in a signal line having a higher fault possibility than others and a test pattern is created as a pair of an input pattern (e.g., a data string such as “0010”) for detecting the assumed fault and an expected value pattern expected to be output when the input pattern is input. Here, test patterns are created such that creating a test pattern for a signal line having a higher fault possibility than others is prioritized. As a result, the created test patterns are to be put in order in which a fault can be discovered efficiently. Using the created test patterns, the testing apparatus tests the manufactured logic IC (S14).

### PRIOR ART DOCUMENT

### Patent Document

### [Patent Document 1]

Japanese Unexamined Patent Publication No. Hei 8(1996)-114656

### SUMMARY OF THE INVENTION

According to the method for creating test patterns for logic ICs described in patent document 1, however, inserting test points is not taken in consideration and the problem encountered by this method is difficulty of executing sufficient tests.

A method for inserting test points for logic circuits pertaining to the present invention estimates fault likelihoods for each of signal lines in a logic circuit in accordance with wiring conditions obtained from design data for the logic circuit and inserts test points, based on the fault likelihoods.

In the present invention, the fault likelihoods for each of signal lines in a logic circuit are estimated, according to the wiring conditions. Test points are inserted in the logic circuit, based on the fault likelihoods. Thereby, it is possible to insert test points in an effective manner.

According to the present invention, it is possible to insert test points in a logic circuit under test in an effective manner.

### BRIEF DESCRIPTION OF THE DRAWINGS

FIG. 1 is a block diagram of a logic circuit testing apparatus pertaining to a first embodiment;

FIG. 2 is a block diagram of a logic IC under test by the logic circuit testing apparatus pertaining to the first embodiment;

FIG. 3 tabulates design data for a logic IC under test by the logic circuit testing apparatus pertaining to the first embodiment;

FIG. 4 is a flowchart illustrating processing by the logic circuit testing apparatus pertaining to the first embodiment;

FIG. 5 is a flowchart illustrating processing by a conventional logic circuit testing apparatus; and

FIG. 6 is a block diagram of a logic circuit under test by the conventional logic circuit testing apparatus.

### DETAILED DESCRIPTION OF THE PREFERRED EMBODIMENT

### First Embodiment

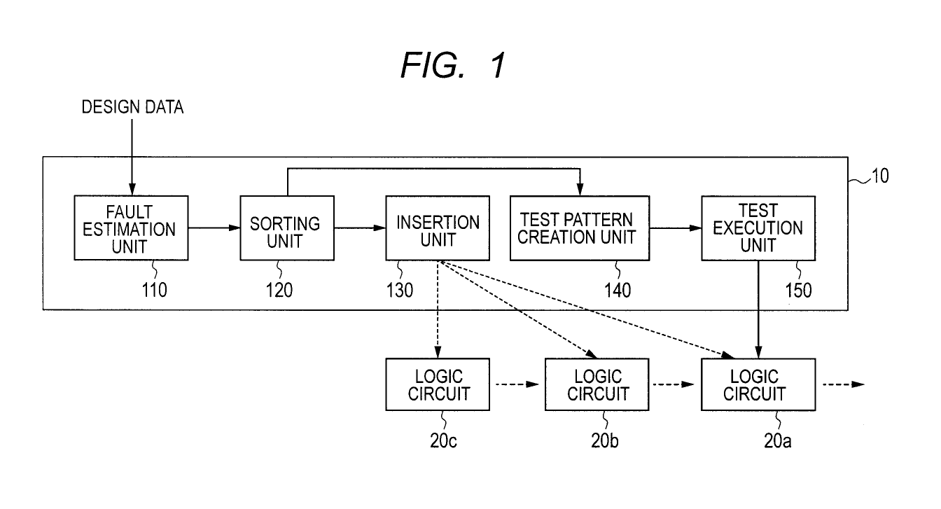

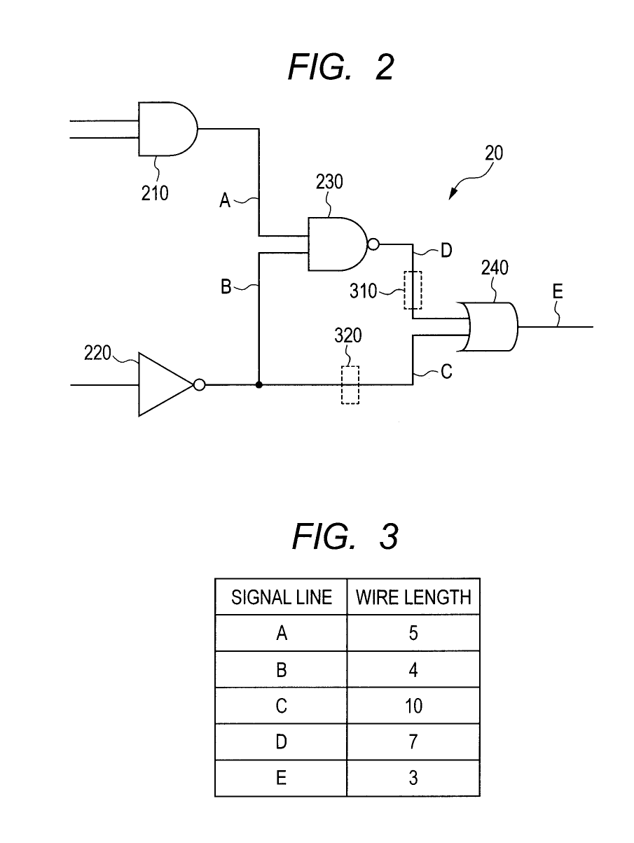

A preferred embodiment of the present invention will be described hereinafter with reference to the drawings. Referring to FIG. 1, a basic configuration of a logic circuit testing apparatus pertaining to the present embodiment is described. The logic circuit testing apparatus 10 comprises a fault estimation unit 110, a sorting unit 120, an insertion unit 130, a test pattern creation unit 140, and a test execution unit 150. The logic circuit testing apparatus 10 is the apparatus for testing logic circuits 20. A logic circuit 20 under test in the present example is shown in FIG. 2. Design data for signal lines in the logic circuit 20 is shown in FIG. 3. The logic circuit 20 comprises logic gates 210, 220, 230, and 240 and signal lines A, B, C, D, E (FIG. 2).

To the fault estimation unit 110, design data for the logic circuit 20 is input from outside of the logic circuit testing apparatus 10. The fault estimation unit 110 estimates the fault possibilities of the signal lines, based on the input design data. In the present example, the fault estimation unit 110 estimates that a signal line whose wire length is longer has a higher fault possibility.

It should be noted that the fault estimation unit 110 may estimate the fault possibilities of the signal lines, using other design data. For example, the fault estimation unit 110 may estimate that a signal line for which the number of alternate routes is larger has a higher fault possibility. In another example, the fault estimation unit 110 may estimate that a signal line for which the wiring density is higher has a higher fault possibility. The fault estimation unit 110 may estimate that a signal line for which the number of intersections with other signal routes in wiring layers is larger has a higher fault possibility. Further, the fault estimation unit 110 may estimate the fault possibilities of the signal lines, taking account of all the following: for each signal line, the wire length, the number of alternate routes, the wiring density, and the number of intersections with other signal routes in wiring layers.

The fault estimation unit 110 outputs the fault possibilities of the signal lines calculated based on the design data to the sorting unit 120.

The sorting unit 120 sorts information for the signal lines in descending order of the fault possibilities of the signal lines calculated by the fault estimation unit 110. In the present example, the sorting unit 120 sorts the information for the signal lines so that the signal lines are reordered as: C (10), D (7), A (5), B (4), and E (3) (the numbers in parentheses denote the wire lengths of the signal lines). The sorting unit 120 outputs the information for the reordered signal lines to the insertion unit 130 and the test pattern creation unit 140.

To the insertion unit 130, the information for the sorted signal lines by the sorting unit 120 is input. The insertion unit 130 inserts test points in the logic circuit 20, using the order indicated by the information for the sorted signal lines by the sorting unit 120. For example, the insertion unit 130 inserts test points on two higher-order signal lines (N 2). In the present example, test points 310, 320 are inserted on a signal line C and a signal line D having higher fault possibilities than others (FIG. 2). The number (N) of test points inserted can be changed optionally.

The insertion unit 130 may insert test points in another way, not restrictive to the manner in which it inserts test points on signal lines having higher fault possibilities than others. For example, the insertion unit 130 may retain a predefined threshold of fault possibilities (e.g., the wire length of a signal line is “5” or above) and may insert test points on signal lines having fault possibilities exceeding the threshold.

To the test pattern creation unit 140, the information for the sorted signal lines by the sorting unit 120 is input. The test pattern creation unit 140 creates test patterns so that tests can be executed in the order of the signal lines sorted by the sorting unit 120. In the present example, the test pattern creation unit creates an input pattern (e.g., 0010) by which a fault such as an open fault or bridging fault of a signal line C can be detected and an output value (e.g., 0000) expected as the output responsive to the input pattern. Then, the test pattern creation unit creates an input pattern (e.g., 0110) by which a fault such as an open fault or bridging fault of a signal line D can be detected and an output value (e.g., 1110) expected as the output responsive to the input pattern. The created input patterns are input to the logic circuit 20, put in the order that allows earlier detection of a malfunction in the signal lines having higher fault possibilities. The test pattern creation unit 140 outputs the created test patterns (input patterns and expected output values) to the test execution unit 150.

The test execution unit 150 executes testing each logic circuit 20, using the test patterns input from the test pattern creation unit 140. Here, the test patterns input from the test pattern creation unit 140 are sorted in the order that allows earlier detection of a malfunction in the signal lines having higher fault possibilities. The test execution unit 150 executes the test patterns and stops the test upon detecting a mismatch between an input pattern and its expected output value, and proceeds to execution of testing the next logic circuit 20. The test execution unit 150 also performs inspection using the test points inserted by the insertion unit 130.

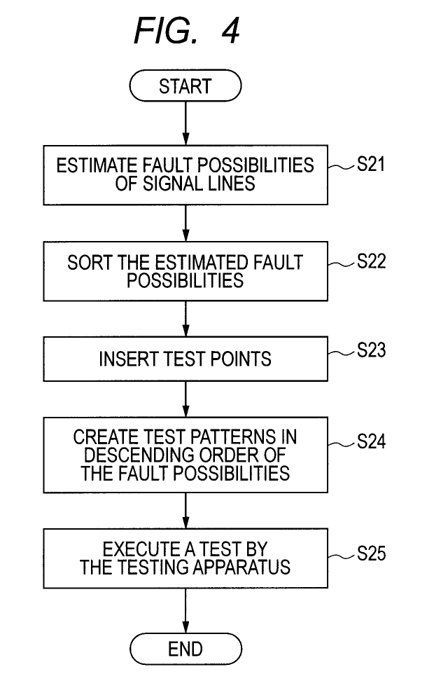

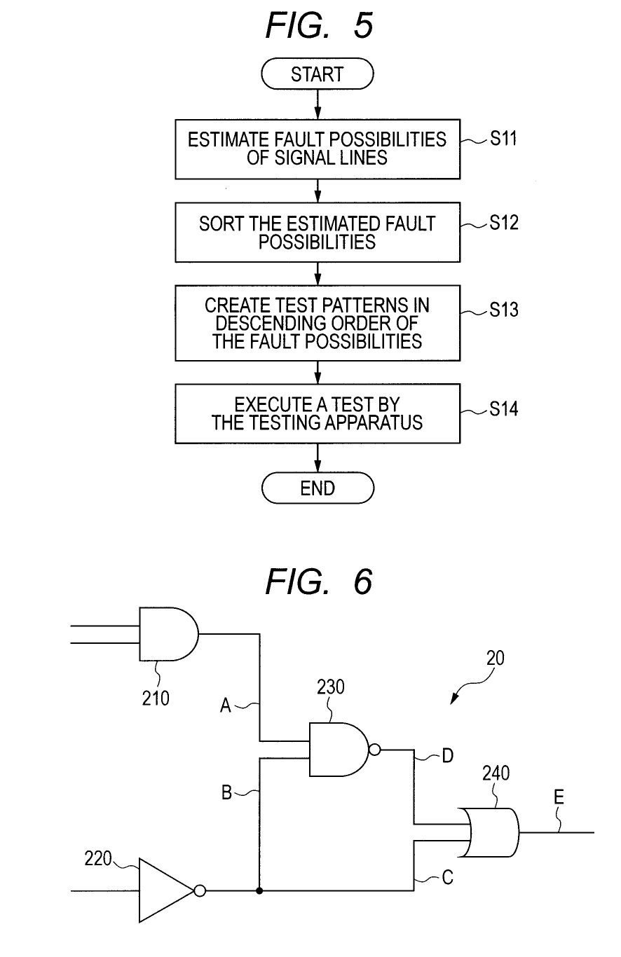

Then, the processing flow that is carried out by the logic circuit testing apparatus 10 pertaining to the present embodiment is described, using the flowchart of FIG. 4. First, design data for a logic circuit 20 is input to the fault estimation unit 110 from outside. The fault estimation unit 110 performs a step of estimating the fault possibilities of the signal lines (S21). Then, the sorting unit 120 sorts the information for the signal lines, based on the fault possibilities calculated by the fault estimation unit 110 (S22).

The insertion unit 130 inserts test points in the logic circuit 20, according to descending order of the fault possibilities sorted by the sorting unit 120. That is, the insertion unit 130 inserts test points in the logic circuit 20, prioritizing test point insertion on a signal line having a higher fault possibility than other signal lines (S23).

The test pattern creation unit 140 creates test patterns, according to descending order of the fault possibilities sorted by the sorting unit 120 (S24). The test execution unit 150 executes testing the logic circuit 20 in which the test points were inserted, using the created test patterns (S25).

In the following, advantages of the above logic circuit testing apparatus are set forth. Through the above-described series of steps, the logic circuit testing apparatus 10 can insert more effective test points by using the design data even before test execution.

The logic circuit testing apparatus 10 can insert test points on signal lines having higher fault possibilities in the logic circuit 20, according to the descending order of the fault possibilities of the signal lines. Thereby, it is possible to efficiently implement the process of inserting test points, which generally entails a high processing cost.

According to the above logic circuit testing apparatus 10, an advantageous effect can be achieved when executing a scan path test of a logic circuit. In this respect, a description will be provided below.

In general, for a scan path test of a logic circuit, terminals in a certain section of the logic circuit under test typically need to be made static so that a given value is output. Such static section is out of the scope of scan path testing. As this static section, by selecting a section that operates less frequently, the malfunction incidence during routine operation of the logic circuit can be kept low. However, the processing speed of a section that operates more frequently is desired to be higher, whereas a high processing speed is less required for a section that operates less frequently. In other words, in a section that operates less frequently, processing timing is less strict. For this reason, in a section that operates less frequently, the wire length of a signal line tends to be longer. As the wire length of a signal line is longer, the number of intersections of the signal line with other signal routes increases accordingly. Consequently, there was a problem in which a section that operates less frequently is not tested by a scan path test, despite the fact that a signal line in such section has a high fault possibility because the signal line is longer or for other reasons.

However, according to the logic circuit testing apparatus 10, the foregoing problem can be solved by inserting a test point in a section where a longer signal line is routed, based on design data. In other words, a section that is hard to test by a scan path test can be tested by inserting a test point in such section. This leads to improving the quality of a logic circuit.

The present invention is not limited to the above-described embodiment and modifications can be made as appropriate without departing from the scope of the invention.

What is claimed is:

1. A method for inserting test points for logic circuits comprising estimating fault likelihoods for each of signal lines in a logic circuit in accordance with wiring conditions obtained from design data for the logic circuit and inserting test points, based on the fault likelihoods.

2. The method for inserting test points for logic circuits according to claim 1, wherein inserting the test points prioritizes test point insertion on a signal line having a higher fault likelihood than other signal lines.

3. The method for inserting test points for logic circuits according to claim 1, further comprising sorting the fault likelihoods, wherein inserting the test points prioritizes test point insertion on a signal line having a higher fault likelihood than other signal lines, based on the sorted fault likelihoods.

4. The method for inserting test points for logic circuits according to claim 1, further comprising setting a predefined threshold for determining whether to insert a test point and inserting test points on signal lines having larger fault likelihoods than the threshold.

5. A logic circuit testing apparatus comprising:
a fault estimation unit that estimates fault likelihoods for each of signal lines in a logic circuit in accordance with wiring conditions obtained from design data for the logic circuit; and
an insertion unit that inserts test points, based on the fault likelihoods.

6. The logic circuit testing apparatus according to claim 5, wherein the insertion unit inserts the test points, prioritizing test point insertion on a signal line having a higher fault likelihood than other signal lines.

7. The logic circuit testing apparatus according to claim 5, further comprising a sorting unit that sorts the fault likelihoods,
wherein the insertion unit inserts the test points, prioritizing test point insertion on a signal line having a higher fault likelihood than other signal lines among the fault likelihoods sorted by the sorting unit.

8. The logic circuit testing apparatus according to claim 5, wherein the insertion unit stores a threshold for determining whether to insert a test point and inserts test points on signal lines having larger fault likelihoods than the threshold.
